(19) United States
(12) Patent Application Publication
(10) Pub. No.: US 2025/0081549 A1
(43) Pub. Date: Mar. 6, 2025

(54) SEMICONDUCTOR DEVICE HAVING NANOSHEET TRANSISTOR AND METHODS OF FABRICATION THEREOF

(71) Applicant: TAIWAN SEMICONDUCTOR MANUFACTURING COMPANY, LTD., Hsinchu (TW)

(72) Inventors: Yu-Yu Chen, New Taipei City (TW); Zheng-Yang Pan, Hsinchu (TW); Ya-Wen Chiu, Tainan (TW)

(21) Appl. No.: 18/239,999

(22) Filed: Aug. 30, 2023

(51) Int. Cl. H01L 29/06; H01L 21/8238; H01L 27/092; H01L 29/417; H01L 29/423; H01L 29/66; H01L 29/775; H01L 29/786

(52) U.S. Cl. CPC H10D 62/121; H10D 30/014; H10D 30/43; H10D 30/6729; H10D 30/6735; H10D 30/6757; H10D 64/017; H10D 84/0167; H10D 84/017; H10D 84/038; H10D 84/85

(57) ABSTRACT

Various embodiments of the present disclosure provide a semiconductor device structure. In one embodiment, the semiconductor device structure includes a plurality of semiconductor layers vertically stacked, a plurality of inner spacers, each being disposed between two adjacent semiconductor layers. The structure also includes a source/drain feature in contact with each of the inner spacers, a gate electrode layer surrounding a portion of each of the plurality of the semiconductor layers, and a cap layer disposed between the source/drain feature and each of the plurality of the semiconductor layers.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. However, such scaling down presents new challenge. For example, transistors using nanostructure channels have been proposed to improve carrier mobility and drive current in a device. An inner spacer is often disposed between metal gate and source/drain (S/D) structure to protect the S/D structure from damage that may occur during the subsequent gate replacement process. Although the formation of the inner spacer has been generally adequate for their intended purposes, they have not been entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-6 are perspective views of various stages of manufacturing a semiconductor device structure in accordance with some embodiments.

FIGS. 7A-17A are cross-sectional side views of various stages of manufacturing the semiconductor device structure taken along cross-section A-A of FIG. 6, in accordance with some embodiments.

FIG. 9A-1 is a cross-sectional side view of the semiconductor device structure, in accordance with some alternative embodiments.

FIGS. 11A-1 and 11A-2 are cross-sectional side views of the semiconductor device structure, in accordance with some alternative embodiments.

FIGS. 11A-2a and 11A-3a are enlarged views of a portion of the semiconductor device structure of FIG. 11A-2, in accordance with some alternative embodiments.

FIGS. 12A-1 and 12A-2 are cross-sectional side views of the semiconductor device structure, in accordance with some alternative embodiments.

FIGS. 17A-1 and 17A-2 are enlarged views of a portion of the semiconductor device structure of FIG. 17A, in accordance with some alternative embodiments.

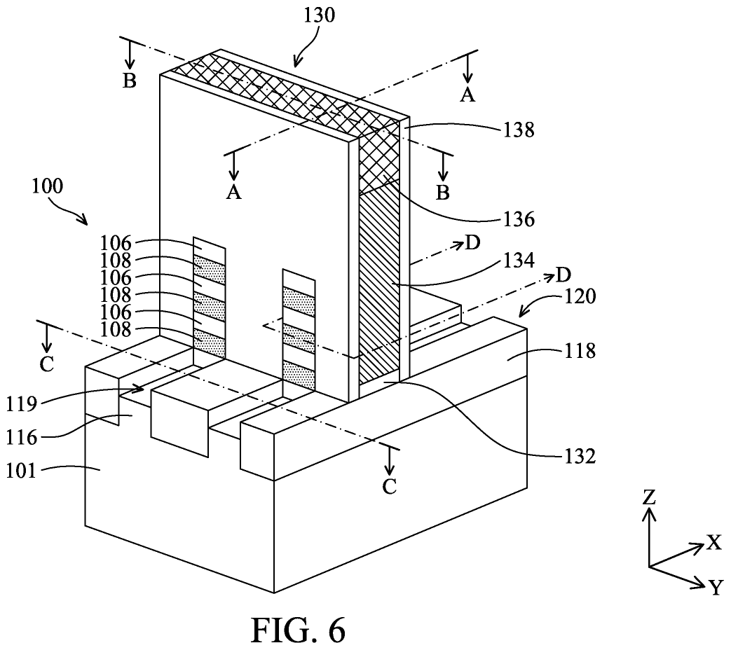

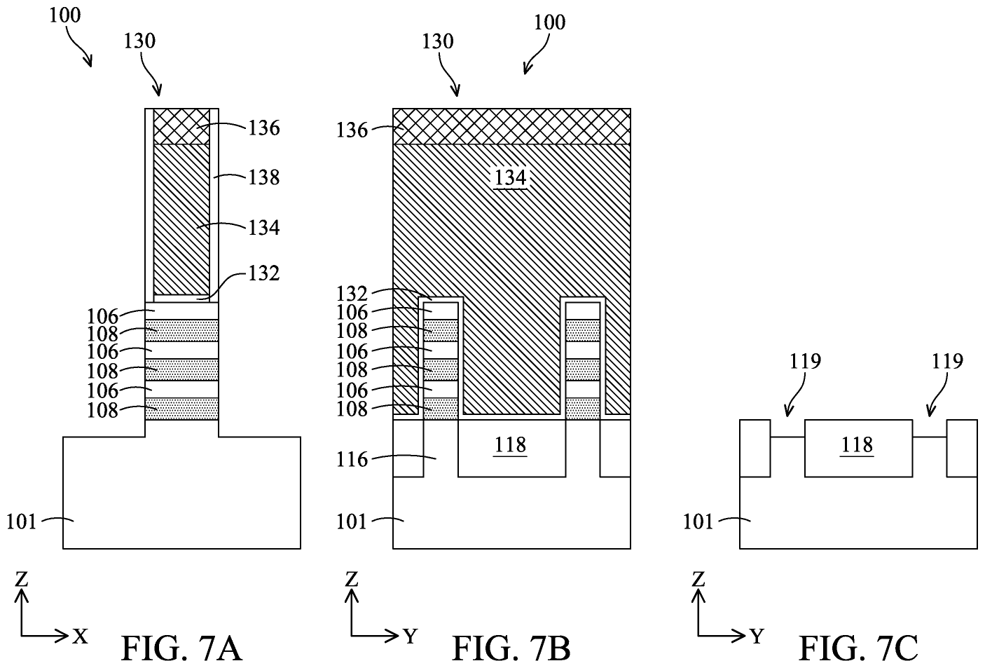

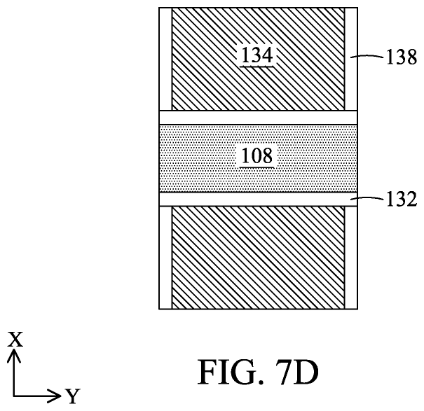

FIGS. 7B-17B are cross-sectional side views of various stages of manufacturing the semiconductor device structure taken along cross-section B-B of FIG. 6, in accordance with some embodiments.

FIGS. 7C-17C are cross-sectional side views of various stages of manufacturing the semiconductor device structure taken along cross-section C-C of FIG. 6, in accordance with some embodiments.

FIGS. 7D-17D are cross-sectional side views of various stages of manufacturing the semiconductor device structure taken along cross-section D-D of FIG. 6, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

While the embodiments of this disclosure are discussed with respect to nanostructure channel FETs, implementations of some aspects of the present disclosure may be used in other processes and/or in other devices, such as planar FETs, Fin-FETs, Horizontal Gate All Around (HGAA) FETs, Vertical Gate All Around (VGAA) FETs, and other suitable devices. A person having ordinary skill in the art will readily understand other modifications that may be made are contemplated within the scope of this disclosure. In cases where gate all around (GAA) transistor structures are adapted, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

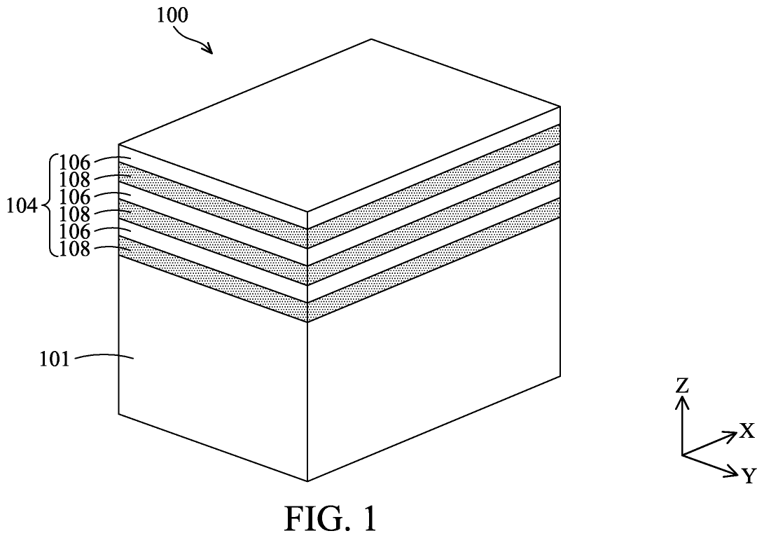

FIGS. 1 to 17D show non-limiting processes for manufacturing a semiconductor device structure 100 according to embodiments of the present disclosure. It is understood that additional operations can be provided before, during, and after processes shown by FIGS. 1 to 17D, and some of the operations described below can be replaced or eliminated, for additional embodiments of the method. The order of the operations/processes is not limiting and may be interchangeable.

FIGS. 1-6 are perspective views of various stages of manufacturing a semiconductor device structure 100 in accordance with some embodiments. As shown in FIG. 1, a semiconductor device structure 100 includes a stack of semiconductor layers 104 formed over a front side of a substrate 101. The substrate 101 may be a semiconductor substrate. The substrate 101 may include a crystalline semiconductor material such as, but not limited to, silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb), indium phosphide (InP), or a combination thereof. In one embodiment, the substrate 101 is made of silicon. The substrate 101 may be doped or un-doped. The substrate 101 may be a bulk semiconductor substrate, such as a bulk silicon substrate that is a wafer, a silicon-on-insulator (SOI) substrate, a multi-layered or gradient substrate, or the like.

The substrate 101 may include various regions that have been doped with impurities (e.g., dopants having p-type or n-type conductivity). Depending on circuit design, the dopants may be, for example phosphorus for an n-type field effect transistors (NFET) and boron for a p-type field effect transistors (PFET).

The stack of semiconductor layers 104 includes alternating semiconductor layers made of different materials to facilitate formation of nanosheet channels in a multi-gate device, such as nanosheet channel FETs. In some embodiments, the stack of semiconductor layers 104 includes first semiconductor layers 106 and second semiconductor layers 108 vertically stacked over the substrate 101. In some embodiments, the stack of semiconductor layers 104 includes alternating first and second semiconductor layers 106, 108. The first semiconductor layers 106 and the second semiconductor layers 108 are made of semiconductor materials having different etch selectivity and/or oxidation rates. For example, the first semiconductor layers 106 may be made of Si and the second semiconductor layers 108 may be made of SiGe. In some examples, the first semiconductor layers 106 may be made of SiGe and the second semiconductor layers 108 may be made of Si. Alternatively, in some embodiments, either of the semiconductor layers 106, 108 may be or include other materials such as Ge, SiC, GeAs, GaP, InP, InAs, InSb, GaAsP, AlInAs, AlGaAs, InGaAs, GaInP, GaInAsP, or any combinations thereof.

The first and second semiconductor layers 106, 108 are formed by any suitable deposition process, such as epitaxy. By way of example, epitaxial growth of the layers of the stack of semiconductor layers 104 may be performed by a molecular beam epitaxy (MBE) process, a metalorganic chemical vapor deposition (MOCVD) process, and/or other suitable epitaxial growth processes.

The first semiconductor layers 106 or portions thereof may form nanosheet channel(s) of the semiconductor device structure 100 in later fabrication stages. The term nanosheet is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanosheet channel(s) of the semiconductor device structure 100 may be surrounded by a gate electrode. The semiconductor device structure 100 may include a nanosheet transistor. The nanosheet transistors may be referred to as nanowire transistors, gate-all-around (GAA) transistors, multi-bridge channel (MBC) transistors, or any transistors having the gate electrode surrounding the channels. The use of the first semiconductor layers 106 to define a channel or channels of the semiconductor device structure 100 is further discussed below.

Each first semiconductor layer 106 may have a thickness in a range between about 5 nm and about 30 nm. Each second semiconductor layer 108 may have a thickness that is equal, less, or greater than the thickness of the first semiconductor layer 106. In some embodiments, each second semiconductor layer 108 has a thickness in a range between about 2 nm and about 50 nm. Three first semiconductor layers 106 and three second semiconductor layers 108 are alternately arranged as illustrated in FIG. 1, which is for illustrative purposes and not intended to be limiting beyond what is specifically recited in the claims. It can be appreciated that any number of first and second semiconductor layers 106, 108 can be formed in the stack of semiconductor layers 104, and the number of layers depending on the predetermined number of channels for the semiconductor device structure 100.

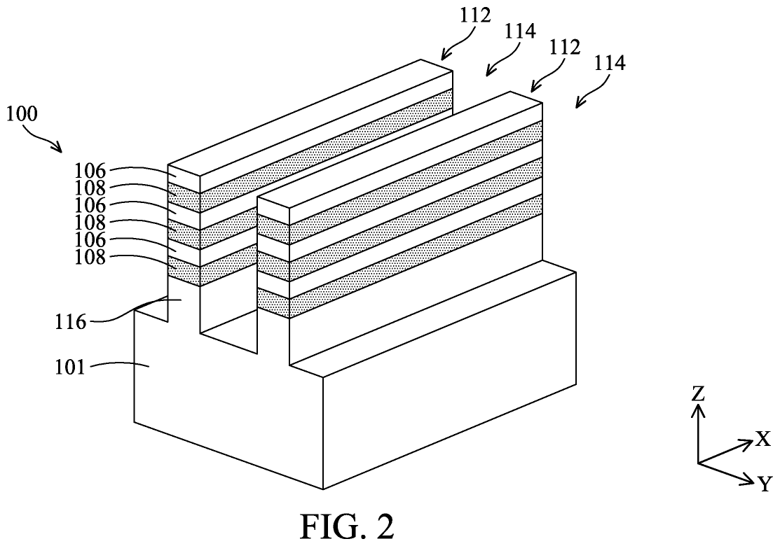

In FIG. 2, fin structures 112 are formed from the stack of semiconductor layers 104. Each fin structure 112 has an upper portion including the semiconductor layers 106, 108 and a well portion 116 formed from the substrate 101. The fin structures 112 may be formed by patterning a hard mask layer (not shown) formed on the stack of semiconductor layers 104 using multi-patterning operations including photo-lithography and etching processes. The etching process can include dry etching, wet etching, reactive ion etching (RIE), and/or other suitable processes. The photo-lithography process may include forming a photoresist layer (not shown) over the hard mask layer, exposing the photoresist layer to a pattern, performing post-exposure bake processes, and developing the photoresist layer to form a masking element including the photoresist layer. In some embodiments, patterning the photoresist layer to form the masking element may be performed using an electron beam (e-beam) lithography process. The etching process forms trenches 114 in unprotected regions through the hard mask layer, through the stack of semiconductor layers 104, and into the substrate 101, thereby leaving the plurality of extending fin structures 112. The trenches 114 extend along the X direction. The trenches 114 may be etched using a dry etch (e.g., RIE), a wet etch, and/or combination thereof.

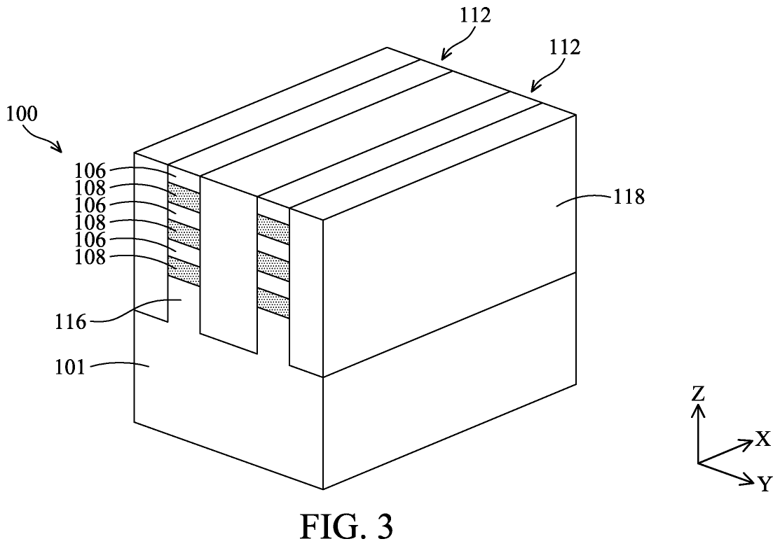

In FIG. 3, after the fin structures 112 are formed, an insulating material 118 is formed on the substrate 101. The insulating material 118 fills the trenches 114 between neighboring fin structures 112 until the fin structures 112 are embedded in the insulating material 118. Then, a planarization operation, such as a chemical mechanical polishing (CMP) method and/or an etch-back method, is performed such that the top of the fin structures 112 is exposed. The insulating material 118 may be made of silicon oxide, silicon nitride, silicon oxynitride (SiON), SiOCN, SiCN, fluorine-doped silicate glass (FSG), a low-K dielectric material, or any suitable dielectric material. The insulating material 118 may be formed by any suitable method, such as low-pressure chemical vapor deposition (LPCVD), plasma enhanced CVD (PECVD) or flowable CVD (FCVD).

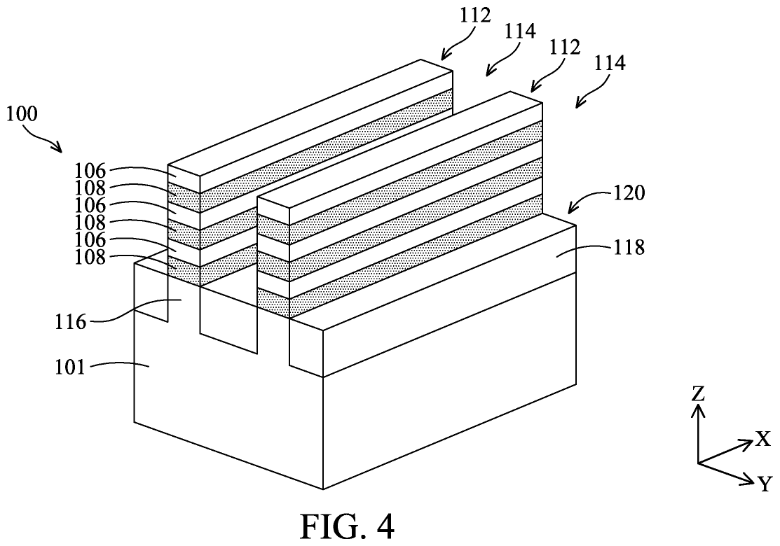

In FIG. 4, the insulating material 118 is recessed to form an isolation region 120. The recess of the insulating material 118 exposes portions of the fin structures 112, such as the stack of semiconductor layers 104. The recess of the insulating material 118 reveals the trenches 114 between the neighboring fin structures 112. The isolation region 120 may be formed using a suitable process, such as a dry etching process, a wet etching process, or a combination thereof. A top surface of the insulating material 118 may be level with or at a below a surface of the second semiconductor layers 108 in contact with the well portion 116 formed from the substrate 101.

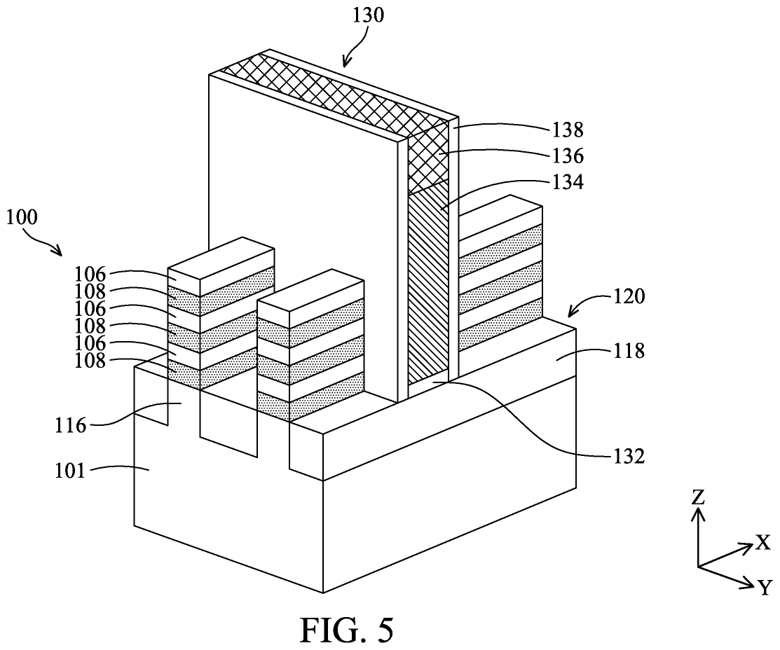

In FIG. 5, one or more sacrificial gate structures 130 (only one is shown) are formed over the semiconductor device structure 100. The sacrificial gate structures 130 are formed over a portion of the fin structures 112. Each sacrificial gate structure 130 may include a sacrificial gate dielectric layer 132, a sacrificial gate electrode layer 134, and a mask layer 136. The sacrificial gate dielectric layer 132, the sacrificial gate electrode layer 134, and the mask layer 136 may be formed by sequentially depositing blanket layers of the sacrificial gate dielectric layer 132, the sacrificial gate electrode layer 134, and the mask layer 136, and then patterning those layers into the sacrificial gate structures 130. Gate spacers 138 are then formed on sidewalls of the sacrificial gate structures 130. The gate spacers 138 may be formed by conformally depositing one or more layers for the gate spacers 138 and anisotropically etching the one or more layers, for example. While one sacrificial gate structure 130 is shown, two or more sacrificial gate structures 130 may be arranged along the X direction in some embodiments.

The sacrificial gate dielectric layer 132 may include one or more layers of dielectric material, such as silicon oxide (SiOₓ) or a silicon oxide-based material. The sacrificial gate electrode layer 134 may include silicon such as polycrystalline silicon or amorphous silicon. The mask layer 136 may include more than one layer, such as an oxide layer and a nitride layer. The gate spacer 138 may be made of a dielectric material such as silicon oxide, silicon nitride, silicon carbide, silicon oxynitride, SiCN, silicon oxycarbide, SiOCN, and/or combinations thereof.

The portions of the fin structures 112 that are covered by the sacrificial gate electrode layer 134 of the sacrificial gate structure 130 serve as channel regions for the semiconductor device structure 100. The fin structures 112 that are partially exposed on opposite sides of the sacrificial gate structure 130 define source/drain (S/D) regions for the semiconductor device structure 100. In some cases, some S/D regions may be shared between various transistors. For example, various one of the S/D regions may be connected together and implemented as multiple functional transistors. It should be understood that the source region and the drain region can be interchangeably used since the epitaxial features to be formed in these regions are substantially the same. Source/drain region(s) may refer to a source or a drain, individually or collectively dependent upon the context.

In FIG. 6, the portions of the fin structures 112 in the S/D regions (e.g., regions on opposite sides of the sacrificial gate structure 130) are recessed down below the top surface of the isolation region 120 (or the insulating material 118), by removing portions of the fin structures 112 not covered by the sacrificial gate structure 130. The recess of the portions of the fin structures 112 can be done by an etch process, either isotropic or anisotropic etch process, or further, may be selective with respect to one or more crystalline planes of the substrate 101. The etch process may be a dry etch, such as a RIE, NBE, or the like, or a wet etch, such as using tetramethyalammonium hydroxide (TMAH), ammonium hydroxide (NH₄OH), or any suitable etchant. Trenches 119 are formed in the S/D regions as the result of the recess of the portions of the fin structures 112.

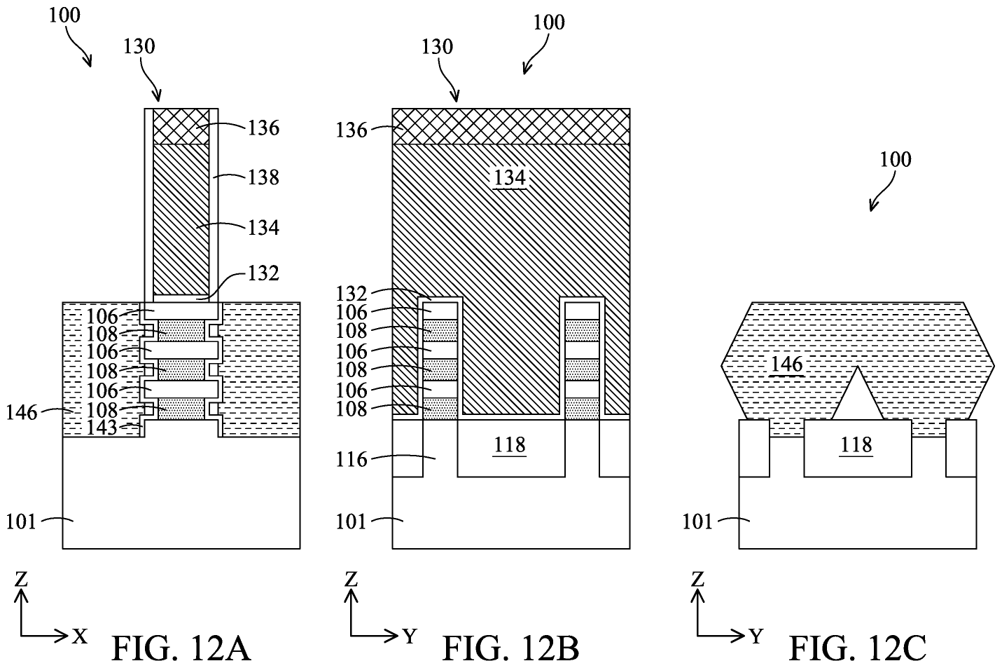

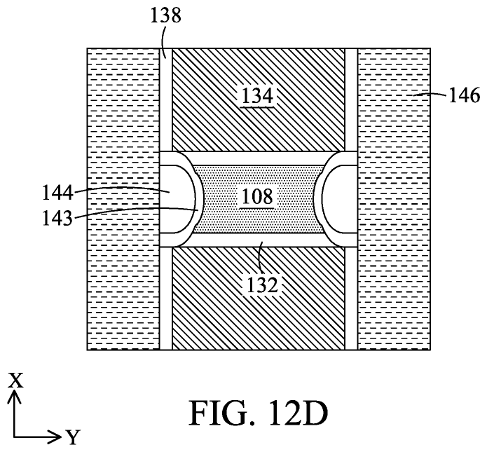

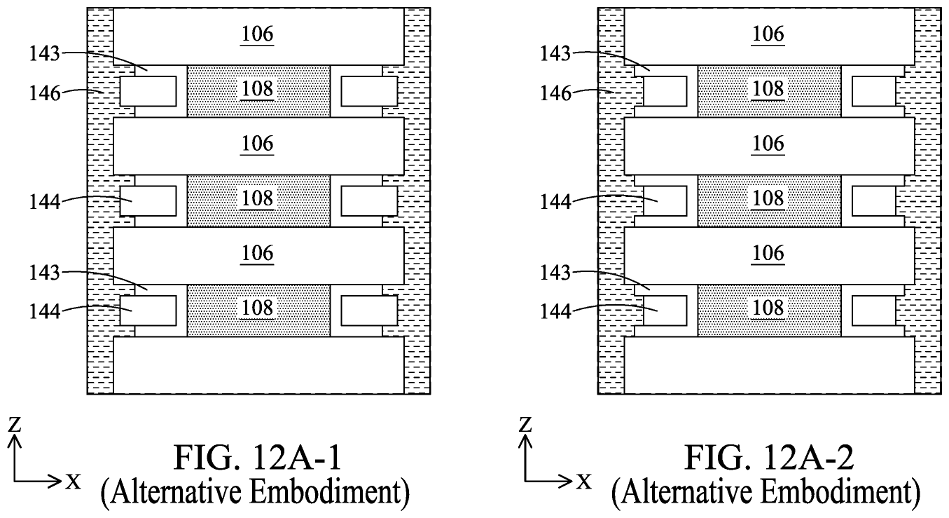

FIGS. 7A-17A are cross-sectional side views of various stages of manufacturing the semiconductor device structure 100 taken along cross-section A-A of FIG. 6, in accordance with some embodiments. FIGS. 7B-17B are cross-sectional side views of various stages of manufacturing the semiconductor device structure 100 taken along cross-section B-B of FIG. 6, in accordance with some embodiments. FIGS. 7C-17C are cross-sectional side views of various stages of manufacturing the semiconductor device structure 100 taken along cross-section C-C of FIG. 6, in accordance with some embodiments. FIGS. 6D-17D are cross-sectional side views of various stages of manufacturing the semiconductor device structure 100 taken along cross-section D-D of FIG. 6, in accordance with some embodiments. Cross-section A-A are in a plane of the fin structure 112 (FIG. 4) along the X direction. Cross-section B-B is in a plane perpendicular to cross-section A-A and is in the sacrificial gate structure 130 along the Y direction. Cross-section C-C is in a plane perpendicular to cross-section A-A and is in the S/D features 146 (FIG. 12A) along the Y-direction. Cross-section D-D is in a plane of the second semiconductor layer 108 along the X direction.

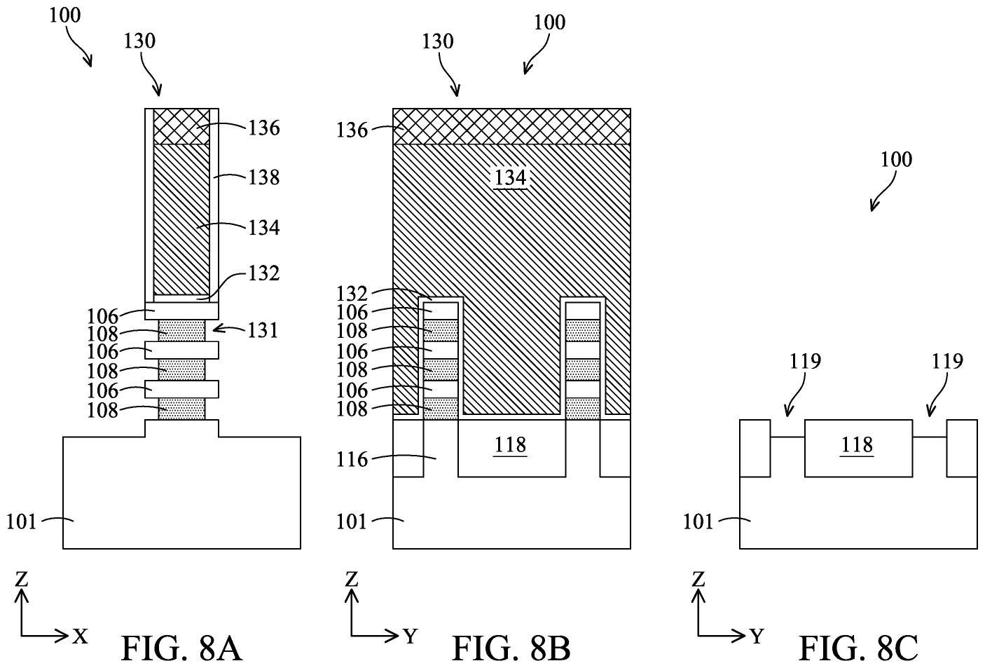

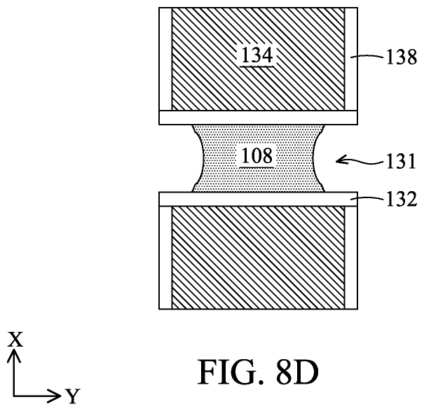

In FIGS. 8A-8D, edge portions of each second semiconductor layer 108 of the stack of semiconductor layers 104 are removed horizontally along the X direction. The removal of the edge portions of the second semiconductor layers 108 forms cavities 131. In some embodiments, the portions of the second semiconductor layers 108 are removed by a selective wet etching process. In cases where the second semiconductor layers 108 are made of SiGe and the first semiconductor layers 106 are made of silicon, the second semiconductor layer 108 can be selectively etched using a wet etchant such as, but not limited to, ammonium hydroxide (NH₄OH), tetramethylammonium hydroxide (TMAH), ethylenediamine pyrocatechol (EDP), or potassium hydroxide (KOH) solutions.

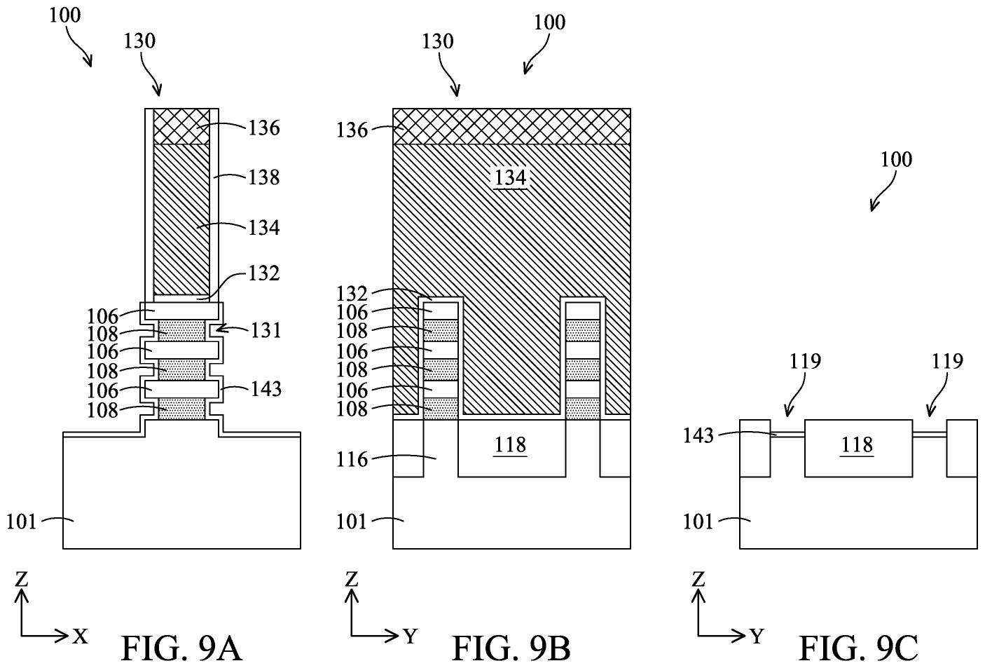

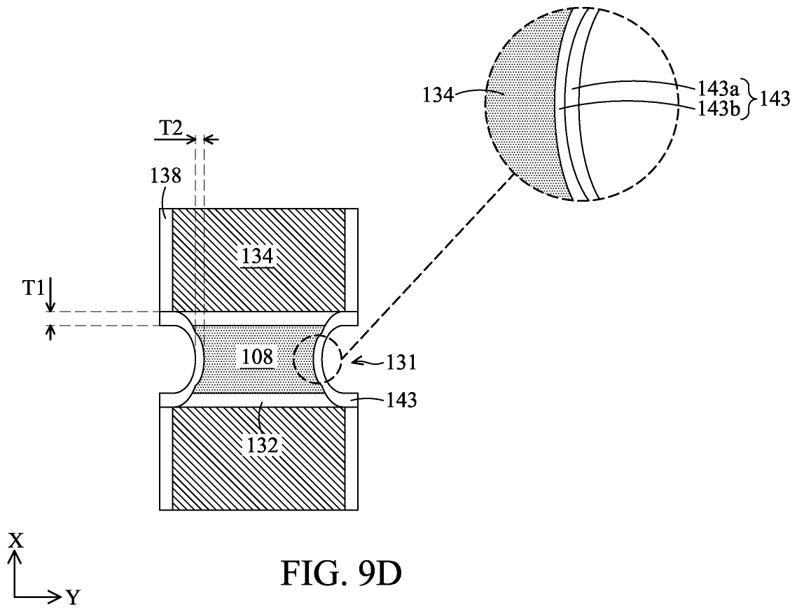

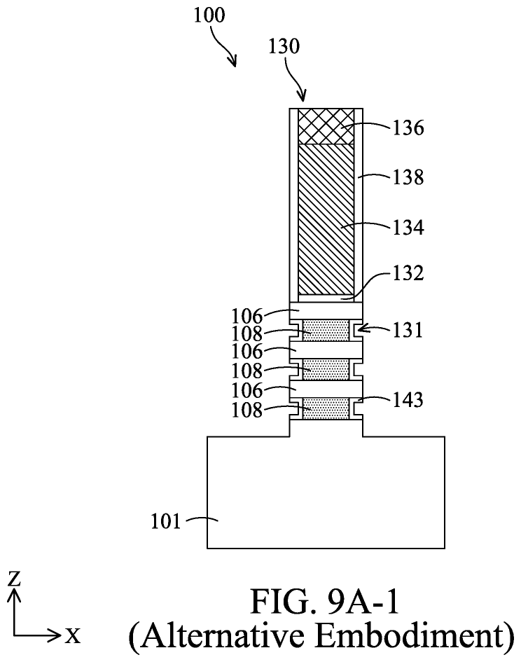

In FIGS. 9A-9D, after removing edge portions of each second semiconductor layers 108, a cap layer 143 is selectively formed on the exposed surfaces of the first semiconductor layers 106, the second semiconductor layers 108, and a portion the exposed wells 116 of the substrate 101. The cap layer 143 may be selectively formed using any suitable selective deposition process, such as cyclic deposition etch (CDE) epitaxy process or selective etch growth (SEG). As will be discussed in more detail below, the precursors and the temperature for forming the cap layer 143 can be controlled to achieve selective or preferential growth of the cap layer 143 on the semiconductor surfaces of the first semiconductor layers 106, the second semiconductor layers 108, and the exposed wells 116 of the substrate 101 over the dielectric surfaces of the sacrificial gate structures 130. Alternatively, the selective deposition of the cap layer 143 may be achieved by first globally formed on the exposed surfaces of the semiconductor device structure 100, followed by one or more selective etch processes (e.g., plasma treatment or atomic layer etch (ALE)) to remove the cap layer 143 from the exposed surfaces of the sacrificial gate structures 130 without damaging the cap layer 143 on the first semiconductor layers 106, the second semiconductor layers 108, and exposed wells 116 of the substrate 101.

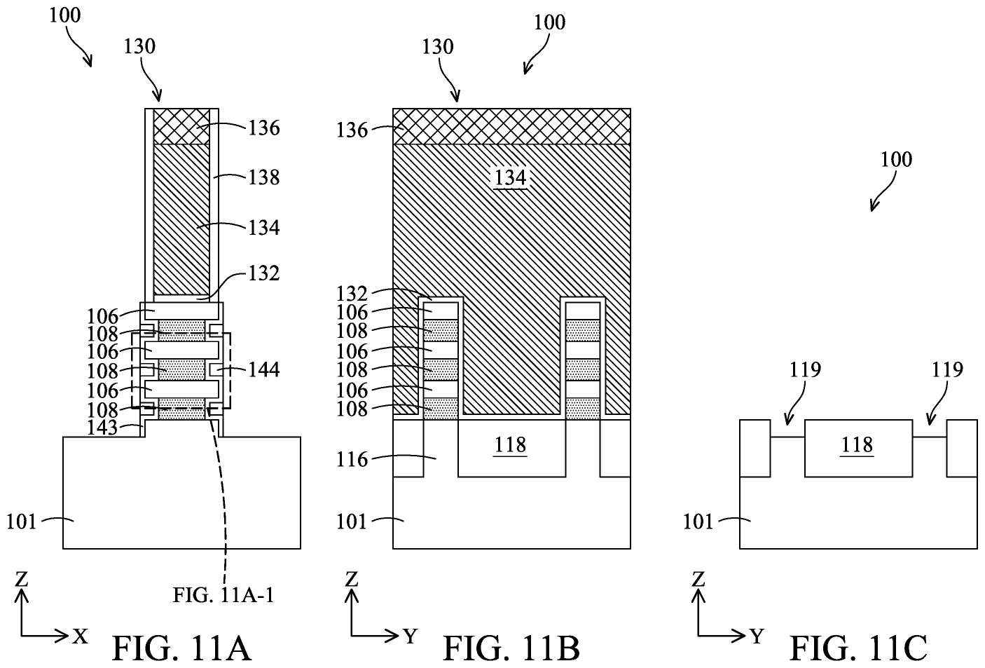

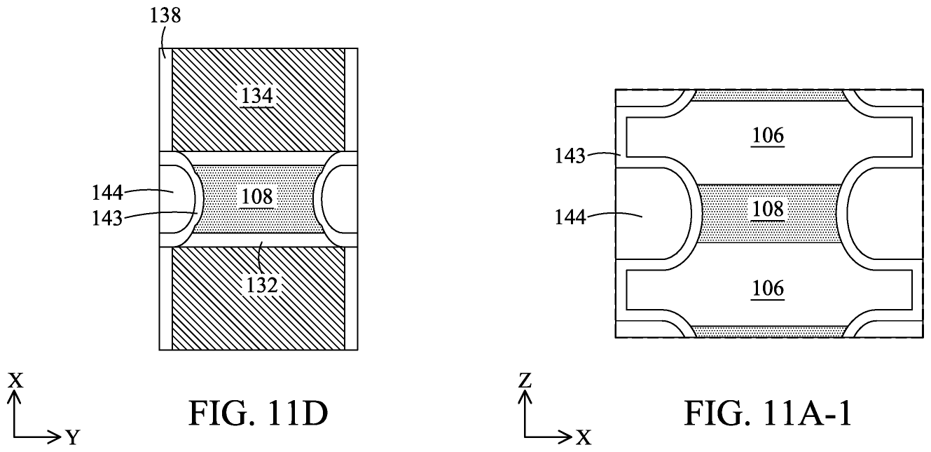

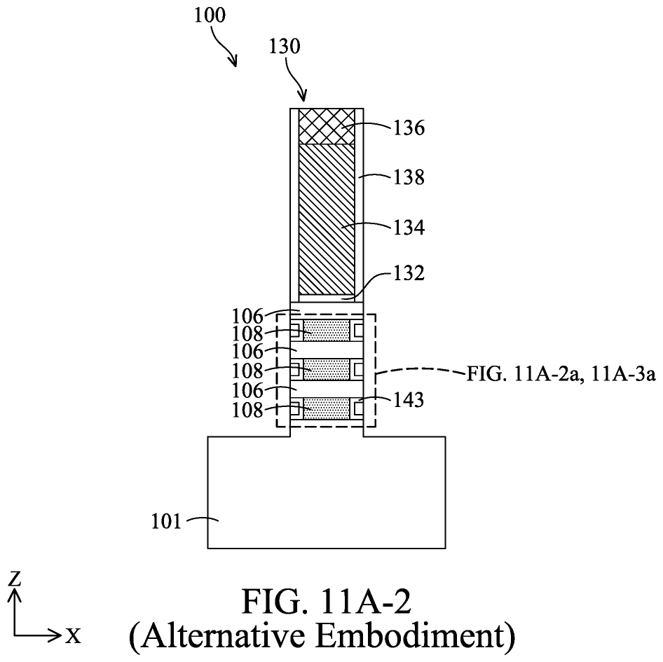

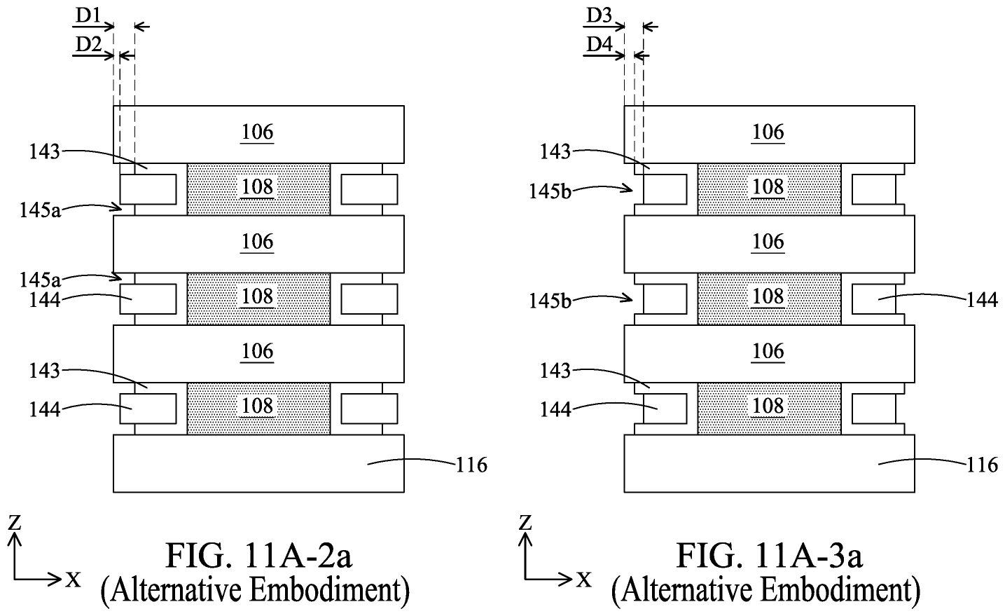

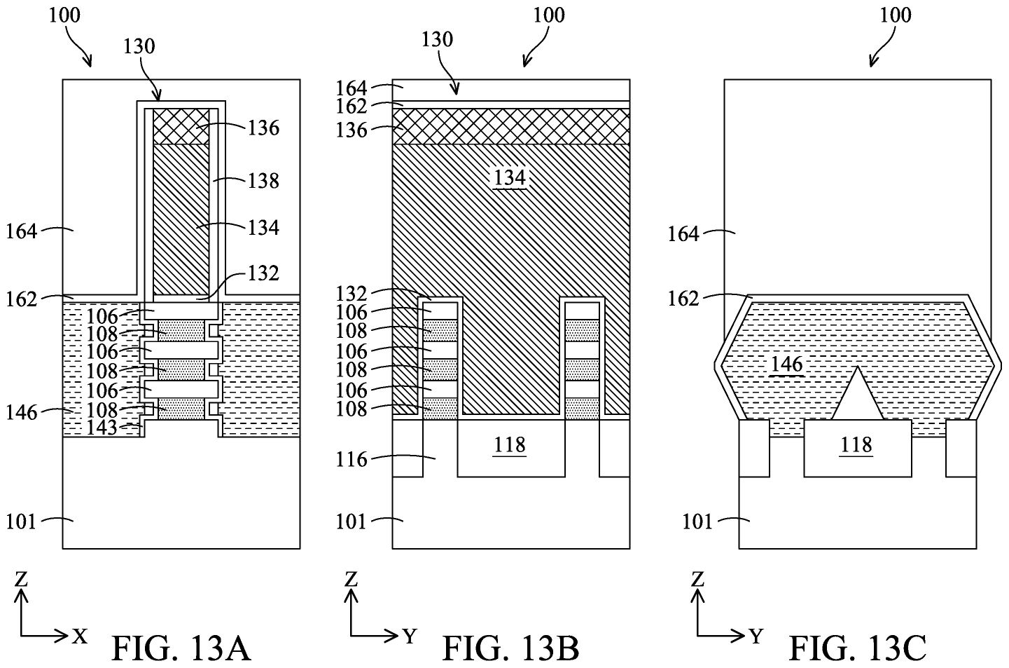

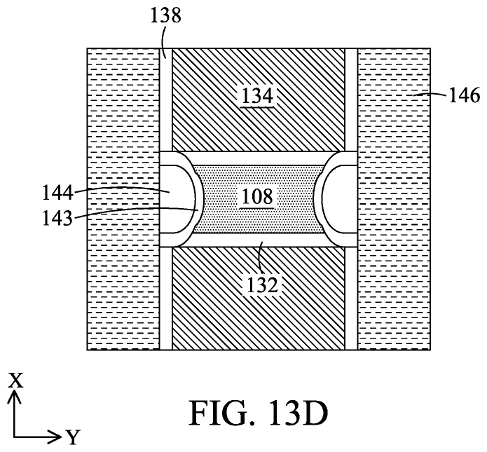

In either case, the cap layer 143 serves as an etch stop layer to prevent etchant chemicals (used during subsequent removal of the second semiconductor layers 108) and/or germanium from breaking through subsequently formed inner spacers 144 (FIGS. 11A and 11B). If the inner spacers 144 are broken, the etch process to remove the second semiconductor layers 108 may also remove subsequently formed S/D features 146 (FIG. 13A). This is because the atomic percentage of germanium of the second semiconductor layers 108 is similar to or lower than that of the material of the S/D features 146 (e.g., SiGe:B). As a result, the S/D features 146 may be damaged or even be removed entirely by the etch process. The formation of the cap layer 143 between the second semiconductor layers 108 and the subsequent inner spacers 144 avoids or minimizes the damage to the inner spacers 144 during removal of the second semiconductor layers 108, thereby protecting the integrality of the S/D features 146. The combined thickness of the cap layer 143 and the inner spacers 144 can avoid reliability issues, such as time dependent dielectric breakdown (TDDB). The cap layer 143 can also reduce (by at least 50%) and/or eliminate Ge diffusion from the second semiconductor layers 108 during subsequent high temperature process, thereby enhancing device performance by at least 2% or more.

The cap layer 143 may be any suitable material that can withstand a chemical attack during subsequent removal of the second semiconductor layers 108. The cap layer 143 may be a semiconductor material, such as silicon. In some embodiments, the cap layer 143 is formed of pure silicon (e.g., intrinsic or undoped) or substantially pure silicon (e.g., substantially free from impurities, for example, with a percentage of impurity lower than about 1 percent). In some embodiments, the cap layer 143 is formed of a doped silicon. In cases where the cap layer 143 is a doped silicon, the dopant of a group III element, such as boron, may be used. In one exemplary embodiment, the cap layer 143 is a boron-doped silicon (Si:B). In various embodiments, the dopant concentration of the cap layer 143 may be in a range from about 1E10¹⁷ cm⁻³ to about 5E20 cm⁻³, such as about 3E21 cm⁻³. It has been observed that the cap layer 143 formed of a boron-doped silicon can effectively retard etch chemicals used to remove the second semiconductor layers 108 during the formation of nanostructure channels in a multi-gate device. As a result, the inner spacers 144 is largely protected. The use of Si:B as the cap layer 143 may be advantageous in some embodiments because the boron dopants may alter crystal orientation of the underlying materials (e.g., first semiconductor layers 106 and the wells 107, 109 of the substrate 101) to promote growth of the subsequent epitaxial S/D features 146 (FIG. 13A) on the cap layer 143.

Alternatively, the cap layer 143 may be made of a dielectric material, such as a nitride. Suitable dielectric materials for the cap layer 143 may include, but are not limited to, SiN, SiCN, SION, SiOCN, or any suitable nitride-based dielectrics. The cap layer 143 may be formed by converting a portion of the first semiconductor layers 106, the second semiconductor layers 108, and the wells 106 of the substrate 101 into a nitride layer. For example, the exposed surfaces of the first semiconductor layers 106, the second semiconductor layers 108, and the wells 106 of the substrate 101 may be subjected to a nitridation process, such as rapid thermal nitridation (RTN) process, high pressure nitridation (HPN) process, decoupled plasma nitridation (DPN) process. Portions of the second semiconductor layers 108, such as the surface portion of the second semiconductor layers 108, may be nitrided after the nitridation process. In cases where the second semiconductor layer 108 is SiGe, a surface portion of the second semiconductor layer 108 may become SiGeN.

In some embodiments, which can be combined with any one or more embodiments of this disclosure, the cap layer 143 may be a multi-layer structure including two or more layers of material discussed herein. In one exemplary embodiment shown in FIG. 9D, for example, the cap layer 143 may include a first sublayer 143a and a second sublayer 143b disposed between the first sublayer 143a and the second semiconductor layer 108. In cases where the cap layer 143 includes SiN, the first sublayer 143a (now outer cap layer) of the cap layer 143 may be SiN having a first nitrogen content and the second sublayer 143b (now inner cap layer) of the cap layer 143 may be SiN having a second nitrogen content lower than the first nitrogen content. That is, the nitrogen content in the cap layer 143 is gradually decreased along a direction away from the surface of the nitrided layer. This applies to the cap layer 143 formed on the first and second semiconductor layers 106, 108 and the wells 106 of the substrate 101. In cases where the cap layer 143 includes SiN and Si:B, the first sublayer 143a (now outer cap layer) of the cap layer 143 may be boron-doped silicon having a first nitrogen content and the second sublayer 143b (now inner cap layer) of the cap layer 143 may be boron-doped silicon having a second nitrogen content lower than the first nitrogen content. In cases where the cap layer 143 includes a first sublayer of SiN and a second sublayer of pure Si, the multi-layer structure may be obtained by nitridizing a portion of the pure Si. In such cases, the first sublayer 143a (now outer cap layer) of the cap layer 143 may be SiN and the second sublayer 143b (now inner cap layer) of the cap layer 143 may remain as pure silicon.

In some embodiments where the cap layer 143 includes silicon (e.g., pure silicon or substantially pure silicon), the selective deposition of the cap layer 143 may be achieved by heating the semiconductor device structure 100 to a temperature of about 400 degrees Celsius to about 600 degrees Celsius, for example about 450 degrees Celsius to about 510 degrees Celsius, and exposing the exposed surfaces of the semiconductor device structure 100 to a precursor including at least a silicon-containing precursor in a reaction chamber (i.e., in-situ). The gas reaction of the silicon-containing precursors promotes silicon growth on the semiconductor surfaces (e.g., exposed surfaces of the first semiconductor layers 106, the second semiconductor layers 108, and wells 116 of the substrate 101) rather than the dielectric surfaces of the sacrificial gate structures 130 (e.g., mask layer 136 and gate spacers 138). Suitable silicon-containing precursor may include, but is not limited to, monosilane (SiH₄), disilane (Si₂H₆), trisilane (Si₃H₈), tetrasilane (Si₄H₁₀), dimethylsilane ((CH₃)₂SiH₂), methylsilane (SiH(CH₃)₃), dichlorosilane (SiH₂Cl₂, DCS), trichlorosilane (SiHCl₃, TCS), or the like. In one embodiment, the cap layer 143 is formed using precursors comprising SiH₄. The formation of the cap layer 143 may be performed in an epitaxial or CVD based reaction chamber.

Additionally or alternatively, the selective deposition of the cap layer 143 may be achieved by heating the semiconductor device structure 100 to a temperature of about 300 degrees Celsius to about 500 degrees Celsius, for example about 360 degrees Celsius to about 420 degrees Celsius, and exposing the exposed surfaces of the semiconductor device structure 100 to a precursor including at least a silicon-containing precursor (as those discussed above) in a reaction chamber (i.e., in-situ) for a short period of time, such as about 3 seconds to about 10 seconds, for example about 5 seconds. In one embodiment, the silicon-containing precursor includes SiH₄ and Si₂H₆. In another embodiment, the silicon-containing precursor includes SiH₄. The cap layer 143 is globally formed on the exposed surfaces of the semiconductor device structure 100, including exposed dielectric surfaces of the sacrificial gate structure 130 and the exposed semiconductor surfaces of the first semiconductor layers 106, the second semiconductor layers 108, and wells 116 of the substrate 101. Due to the short incubation time and the nature of silicon being preferred over semiconductor surfaces than the dielectric surfaces, the amount of the cap layer 143 on the dielectric surfaces of the sacrificial gate structure 130 is a lot less than the amount of the cap layer 143 on the semiconductor surfaces of the first semiconductor layers 106, the second semiconductor layers 108, and wells 116 of the substrate 101. Thereafter, the semiconductor device structure 100 is subjected to a treatment process to remove the cap layer 143 from the dielectric surfaces of the sacrificial gate structure 130, resulting in selective deposition of the cap layer 143 on the exposed semiconductor surfaces of the first semiconductor layers 106, the second semiconductor layers 108, and wells 116 of the substrate 101. In some embodiments, portions of the gate spacers 138, the sacrificial gate dielectric layer 132, and optionally the sacrificial gate electrode layer 132 within the cavities 131 may remain in contact with the cap layer 143, as shown in FIG. 9D.

The treatment process can be an etch process using plasma or a radical of species. For example, the treatment process may use reactive species generated from hydrogen-containing gases in-situ in a reaction chamber or in the upstream of a reaction chamber (e.g., from a remote plasma generator). Exemplary reactive species may include hydrogen plasma or neutral radical species, such as hydrogen radicals or atomic hydrogen. In some embodiments, the treatment process is a plasma treatment process. The plasma treatment may be any suitable plasma process, such as a decoupled plasma process, a remote plasma process, or a combination thereof. The plasma may be formed by a capacitively coupled plasma (CCP) source or an inductively coupled plasma (ICP) source driven by an RF power generator. In cases where ICP source is used, the plasma treatment may be performed in a remote plasma generator having a chamber wall, a ceiling, and a plasma source power applicator comprising a coil antenna disposed over the ceiling and/or around the chamber wall. The plasma source power applicator is coupled through an impedance match network to an RF power source, which may use a continuous wave RF power generator or a pulsed RF power generator operating on a predetermined duty cycle. The source power ionizes the hydrogen-containing gases supplied to the remote plasma generator. The generated hydrogen ions may be filtered by a grounded showerhead disposed in the remote plasma generator to generate neutral radical species (e.g., hydrogen radicals) prior to supplying to a process chamber in which the semiconductor device structure 100 is disposed. In one exemplary embodiment, the decoupled plasma process is formed by the ICP source driven by the RF power generator using a tunable frequency ranging from about 2 MHz to about 13.56 MHZ, and the chamber is operated at a pressure in a range of about 10 mTorr to about 1 Torr and a temperature of about 25 degrees Celsius to about 300 degrees Celsius for a process time of about 15 seconds to about 1 minute. The RF power generator is operated to provide power between about 50 watts to about 1000 watts, and the output of the RF power generator is controlled by a pulse signal having a duty cycle in a range of about 20% to about 80%.

In cases where the cap layer 143 includes boron-doped silicon, the selective deposition of the cap layer 143 may be achieved by a CDE epitaxy process. The CDE epitaxy process may be performed in a process chamber at a temperature in a range between about 300° C. and 800° C., under a pressure in a range between about 1 Torr and 760 Torr, and performed for a time duration in a range between about 20 seconds and 300 seconds, by exposing the semiconductor device structure 100 to a gas mixture comprising one or more silicon-containing precursors, a p-type dopant gas, and a carrier gas for a first period of time to form a first portion of the cap layer 143, followed by a selective etch where the first portion of the cap layer 143 is exposed to etching gas for a second period of time to selectively remove amorphous or polycrystalline portions of the cap layer 143 while leaving crystalline portions of the cap layer 143 intact. The process chamber may be flowed with a purge gas (e.g., N₂) between the epitaxial growth and the selective etch. Suitable gases for the silicon-containing precursor can be those discussed above. Suitable boron-containing precursor may include, but are not limited to, borane (BH₃), diborane (B₂H₆), boron trichloride (BCl₃), triethyl borate (TEB), borazine (B₃N₃H₆), or an alkyl-substituted derivative of borazine, or the like. In cases etching gas(es) is used (e.g., in CDE epitaxy process or SEG process), the deposition process may use one or more etching gases. Suitable etching gases may include, but are not limited to, hydrogen chloride (HCl), a chlorine gas (Cl₂), or the like. A diluent/purge gas, such as hydrogen (H₂), nitrogen (N₂), and/or argon (Ar), may be used along with the precursors for the cap layer 143. In one embodiment, the cap layer 143 is formed using precursors comprising SiH₄ and DCS, and B₂H₆. The formation of the cap layer 143 may be performed in an epitaxial or CVD based reaction chamber. The silicon-containing precursor(s) may be provided at a flow rate in a range between about 10 sccm and about 100 sccm, the dopant gas may be provided at a flow rate in a range between about 50 sccm and about 100 sccm, the carrier gas may be provided at a flow rate in a range between about 0 sccm and about 50000 sccm, and the purge gas may be provided at a flow rate in a range between about 0 sccm and about 50000 sccm. The epitaxial growth and selective etch of the CDE epitaxy process are repeated until a desired thickness the cap layer 143 and above-mentioned dopant concentration are achieved.

FIG. 9A-1 illustrates an alternative embodiment where the cap layer 143 is formed on the first and second semiconductor layers 106, 108 within the cavities 131. In this embodiment, the cap layer 143 may be first deposited on the exposed surfaces of the sacrificial gate structures 130, the first semiconductor layers 106, and the second semiconductor layers 108 using a conformal deposition process, such as ALD. The precursors may be chosen to make the conformal deposition process a non-selective deposition process, meaning the cap layer 143 is globally formed on the exposed surfaces of the sacrificial gate structures 130 (e.g., mask layer 136 and gate spacers 138), the first semiconductor layers 106, the second semiconductor layers 108, the sacrificial gate dielectric layer 132, and the wells 116 of the substrate 101. After the cap layer 143 is formed, a suitable etch process may be performed so that the cap layer 143 on the exposed surfaces of the semiconductor device structure 100 is etched. Since the cap layer 143 within the cavities 131 is more difficult for the etchant to reach, the etch process may remove the cap layer 143 on the sacrificial gate structure 130, the first semiconductor layers 106, and the wells 106 of the substrate 101 at a faster rate than that of the cap layer 143 on the second semiconductor layer 108. As a result, the entire cap layer 143 on the sacrificial gate structure 130, the first semiconductor layers 106, and the wells 106 of the substrate 101 is removed, while the cap layer 143 on the first and second semiconductor layers 106, 108 within the cavities 131 is slightly removed, as shown in FIG. 9A-1. One exemplary etch process may include exposing the exposed surfaces of the sacrificial gate structures, the first semiconductor layers 106, the second semiconductor layers 108, the sacrificial gate dielectric layer 132, and the wells 116 of the substrate 101 to fluorine (F) radicals or a gas mixture comprising hydrogen fluoride (HF) and ammonia (NH₃) at a chamber temperature of about 0° C. to about 50° C., and a chamber pressure of about 100 mTorr to about 500 mTorr. In some embodiments, the HF and NH₃ may be flowed into the process chamber at a flow rate ratio of about 1 (HF):5 (NH₃) to about 1 (HF):10 (NH₃).

In any case, the cap layer 143 as shown in FIG. 9D may have a thickness of about 3 Å to about 30 Å, for example about 8 Å. If the thickness is less than about 3 Å, the cap layer 143 may not effectively block the etchant used during removal of the second semiconductor layer 108. On the other hand, if the thickness is greater than 30 Å, there may be not enough room for the subsequent inner spacer 144 and therefore diminish the effectiveness of the inner spacer 144. In addition, a thick cap layer 143 may also occupy too much space needed for forming the subsequent metal gates. Due to the recess at the edges of the second semiconductor layers 108, the etch reaction at and/or near the edge regions of the second semiconductor layers 108 may be less effective. Therefore, the cap layer 143 in contact with the gate spacer 138 and the sacrificial gate dielectric layer 132 may have the thickness T1 and the cap layer 143 over the second semiconductor layer 108 may have a thickness T2 greater than the thickness T1. In such cases, the thickness T2 may be about 5% to about 20% greater than the thickness T1.

It is contemplated that the cap layer 143 at and/or adjacent the second semiconductor layers 108 may have a shape in accordance with the profile of the recessed second semiconductor layer 108. In the embodiments shown in FIGS. 9D, the cap layer 143 is formed to have a curved profile (e.g., concave shape) when viewed from the top. In some embodiments, the cap layer 143 may have a square or rectangular shape when viewed from the top, which may vary depending on the edge profile of the recessed second semiconductor layer 108.

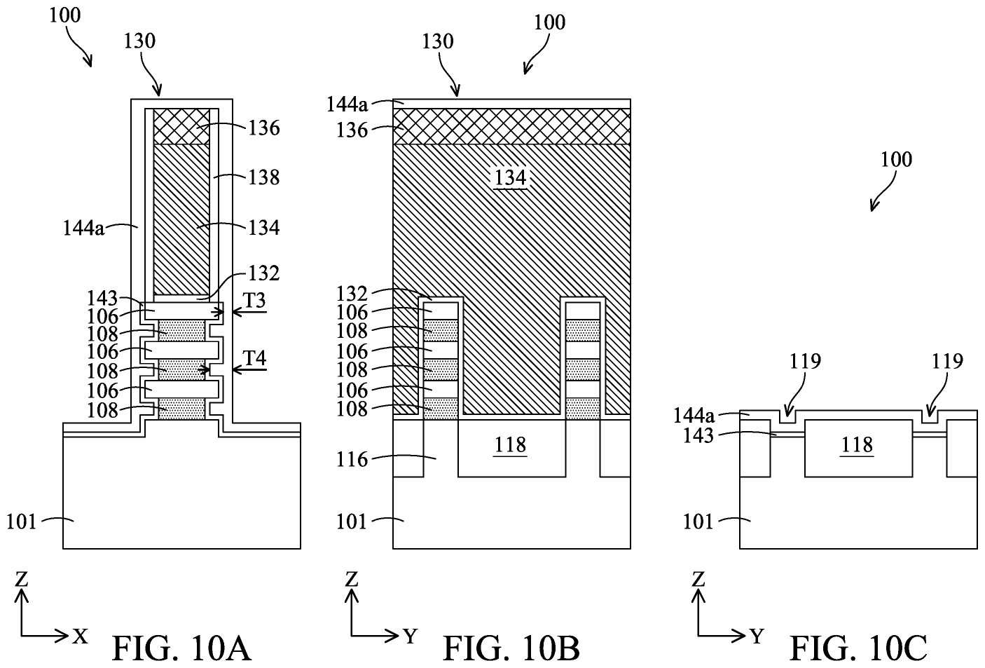

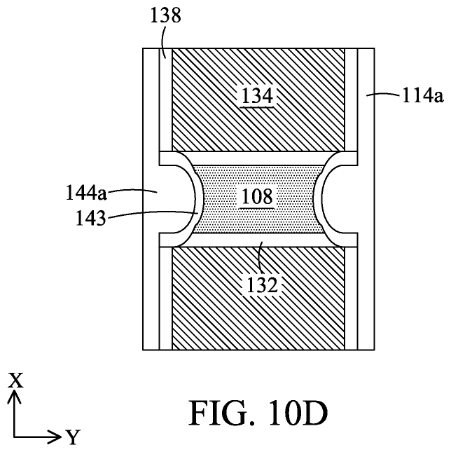

In FIGS. 10A-10D, a dielectric layer 144a is deposited on the exposed surfaces of the semiconductor device structure 100. The dielectric layer 144a also fills the cavities 131 (FIG. 8A) formed as a result of removal of the edge portions of the second semiconductor layers 108. The dielectric layer 144a may be made of a dielectric material that is different from the material of the cap layer 143. Suitable materials for the dielectric layer 144a may include, but are not limited to, SiO₂, Si₃N₄, SiC, SiCP, SION, SiOC, SiCN, SiOCN, and/or other suitable material. Other materials, such as low-k materials with a k value less than about 3.5, may also be used. The formation of the dielectric layer 144a may be formed by a conformal deposition process, such as ALD. The thickness T3 of the dielectric layer 144a adjacent the first semiconductor layers 106 (and wells 116 of the substrate 101) may be in a range of about 1 nm to about 4 nm, while the thickness T4 of the dielectric layer 144a adjacent the second semiconductor layers 108 may be in a range of about 2 nm to about 10 nm. In some embodiments, the dielectric layer 144a is a single layer structure. In some embodiments, the dielectric layer 144a is a multi-layer structure including two or more of the materials discussed herein.

In FIGS. 11A-11D, an etch process is performed such that only portions of the dielectric layer 144a remain in the cavities 131 (FIG. 9A) to form inner spacers 144. The removal process may be any suitable etch processes, such as dry etch, wet etch, or a combination thereof. The etch process may be a selective etch process using an etchant that selectively removes the dielectric layer 144a without substantially removing the cap layer 143. The removal of the portions of the dielectric layer 144a may be performed by an anisotropic etching. The dielectric layer 144a within the cavities 131 are protected by the first semiconductor layers 106 and the cap layer 143 during the anisotropic etching process. The remaining second semiconductor layers 108 are capped between the inner spacers 144 along the X direction. As shown in FIG. 11D, the exposed surfaces of the cap layer 143 and the inner spacer 144 within the cavities 131 are substantially co-planar or flushed with a sidewall surface of the gate spacer 138 when viewing from the top. In some embodiments, the cap layer 143 on the wells 106 of the substrate 101 is also removed.

FIG. 11A-1 illustrates an enlarged view of a portion of the semiconductor device structure 100 shown in FIG. 11A, in accordance with some embodiments. In this embodiment, the dimension of the inner spacer 144 along the Z direction is greater than the dimension of the second semiconductor layer 108 along the Z direction. Particularly, the cap layer 143 is a continuous layer disposed between and in contact with the inner spacer 144, the first semiconductor layer 106, the second semiconductor layer 108, and the subsequent epitaxial S/D features 146 (FIG. 12A). The cap layer 143 is extended to separate the first semiconductor layers 106 from the inner spacers 144. Each of the inner spacers 144 are separated from the adjacent semiconductor layers (e.g., first and second semiconductor layers 106, 108) by the cap layer 143.

FIG. 11A-2 illustrates a stage of the semiconductor device structure 100 after formation of the inner spacer 144 based on the embodiment of FIG. 9A-1. In some embodiments, the duration of the selective etch process may be controlled so that not only the cap layer 143 on first surfaces (i.e., vertical surfaces along the Z direction) of the first semiconductor layers 106 is removed, but a portion of the cap layer 143 on the second surfaces (i.e., horizontal surfaces along the X direction) of the first semiconductor layers 106 is also removed. In these embodiments, the etchant used during the removal of portions of the dielectric layer 144a may etch both the dielectric layer 144a and the cap layer 143 within the cavities 131 (FIG. 9A). The dielectric layer 144a is etched at a first removal rate and the cap layer 143 is etched at a second removal rate. In some embodiments, the second removal rate is greater than the first removal rate, resulting in a recess distance D1 (measured from an edge of the first semiconductor layer 106 to an edge of the cap layer 143) of the cap layer 143 that is larger than a recess distance D2 (measured from the edge of the first semiconductor layer 106 to an edge of the inner spacer 144) of the inner spacer 144, as shown in FIG. 11A-2a. Particularly, the recess distance D1 forms a gap 145a that can be generally defined by the first semiconductor layer 106, the cap layer 143, and the inner spacer 144. The removal of a portion of the cap layer 143 between the inner spacers 144 and the first semiconductor layers 106 may result in a substantial C-shape or U-shape structure of the cap layer 143 sandwiched between the adjacent first semiconductor layers 106. The remaining cap layer 143 is in contact with the first semiconductor layers 106, the second semiconductor layers 108, and the inner spacers 144. The gap 145 may later be filled with the S/D features 146 (FIG. 12A).

In some embodiments, the first removal rate is greater than the second removal rate, resulting in a recess distance D3 (measured from an edge of the first semiconductor layer 106 to an edge of the inner spacer 144) of the inner spacer 144 that is larger than a recess distance D4 (measured from the edge of the first semiconductor layer 106 to the edge of the cap layer 143) of the cap layer 143, as shown in FIG. 11A-3a. Likewise, the recess distance D3 forms a gap 145b that can be generally defined by the cap layer 143 and the inner spacer 144.

In FIGS. 12A-12D, epitaxial S/D features 146 are formed in the source/drain (S/D) regions. The epitaxial S/D features 146 may grow laterally from the first semiconductor layers 106. The epitaxial S/D feature 146 may include one or more layers of Si, SiP, SiC and SiCP for an n-type FET or Si, SiGe, Ge for a p-type FET. The epitaxial S/D features 146 may be formed by an epitaxial growth method using selective epitaxial growth (SEG), CVD, ALD or MBE. The second semiconductor layer 108 under the sacrificial gate structure 130 are separated from the epitaxial S/D features 146 by the dielectric spacers 144. The epitaxial S/D features 146 may grow both vertically and horizontally to form facets, which may correspond to crystalline planes of the material used for the first semiconductor layers 106. In some cases, the epitaxial S/D features 146 of a fin structure may grow and merge with the epitaxial S/D features 146 of the neighboring fin structures, as one example shown in FIG. 12C.

The epitaxial S/D features 146 may be the S/D regions. For example, one of a pair of epitaxial S/D features 146 located on one side of the sacrificial gate structures 130 may be a source region, and the other of the pair of epitaxial S/D features 146 located on the other side of the sacrificial gate structures 130 may be a drain region. A pair of S/D epitaxial features 146 includes a source epitaxial feature 146 and a drain epitaxial feature 146 connected by the channels (i.e., the first semiconductor layers 106). Source/drain region(s) may refer to a source or a drain, individually or collectively dependent upon the context. In this disclosure, a source and a drain are interchangeably used, and the structures thereof are substantially the same.

In cases where embodiment of FIG. 11A-2 is adapted, the epitaxial S/D features 146 may also be in contact with the first semiconductor layers 106, inner spacers 144, and a portion of the cap layer 143. FIGS. 12A-1 and 12A-2 illustrate a stage of the semiconductor device structure 100 after formation of the epitaxial S/D features 146 based on the embodiment of FIGS. 11A-2a and 11A-3a, respectively, in accordance with some embodiments. As can be seen, the epitaxial S/D features 146 grow into the gap 145a (FIG. 11A-2a) and the gap 145b (FIG. 11A-3a) and in contact with the first semiconductor layers 106, inner spacers 144, and the cap layer 143.

In FIGS. 13A-13D, a contact etch stop layer (CESL) 162 is conformally formed on the exposed surfaces of the semiconductor device structure 100. The CESL 162 covers the top surfaces of the sacrificial gate structure 130, the insulating material 118, the epitaxial S/D features 146, and the exposed surface of the stack of semiconductor layers 104. The CESL 162 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD. ALD, or any suitable deposition technique. Next, a first interlayer dielectric (ILD) layer 164 is formed on the CESL 162 over the semiconductor device structure 100. The materials for the first ILD layer 164 may include compounds comprising Si, O, C, and/or H, such as silicon oxide, TEOS oxide, SiCOH and SiOC. Organic materials, such as polymers, may also be used for the first ILD layer 164. The first ILD layer 164 may be deposited by a PECVD process or other suitable deposition technique. In some embodiments, after formation of the first ILD layer 164, the semiconductor device structure 100 may be subject to a thermal process to anneal the first ILD layer 164.

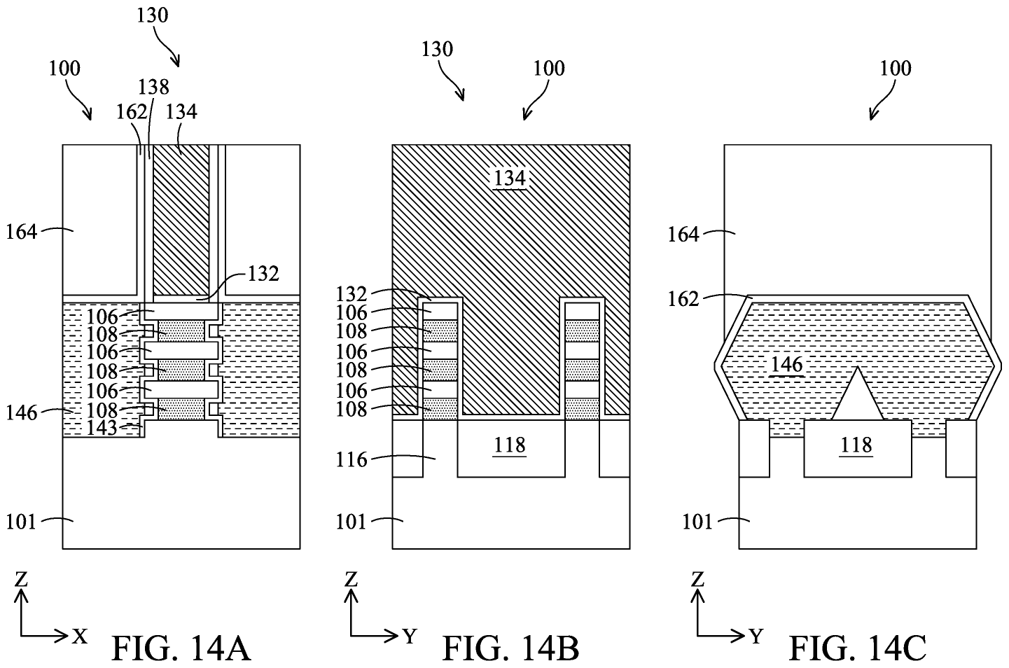

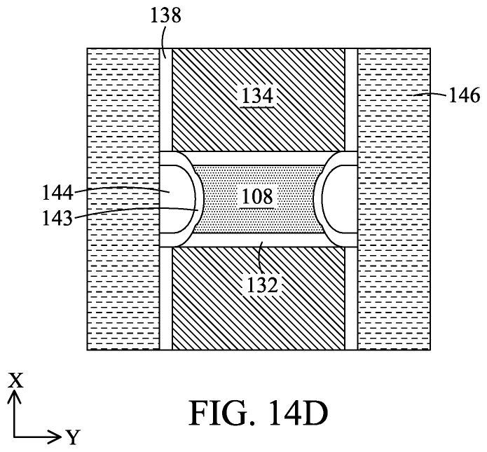

In FIGS. 14A-14D, after the first ILD layer 164 is formed, a planarization operation, such as CMP, is performed on the semiconductor device structure 100 until the sacrificial gate electrode layer 134 is exposed.

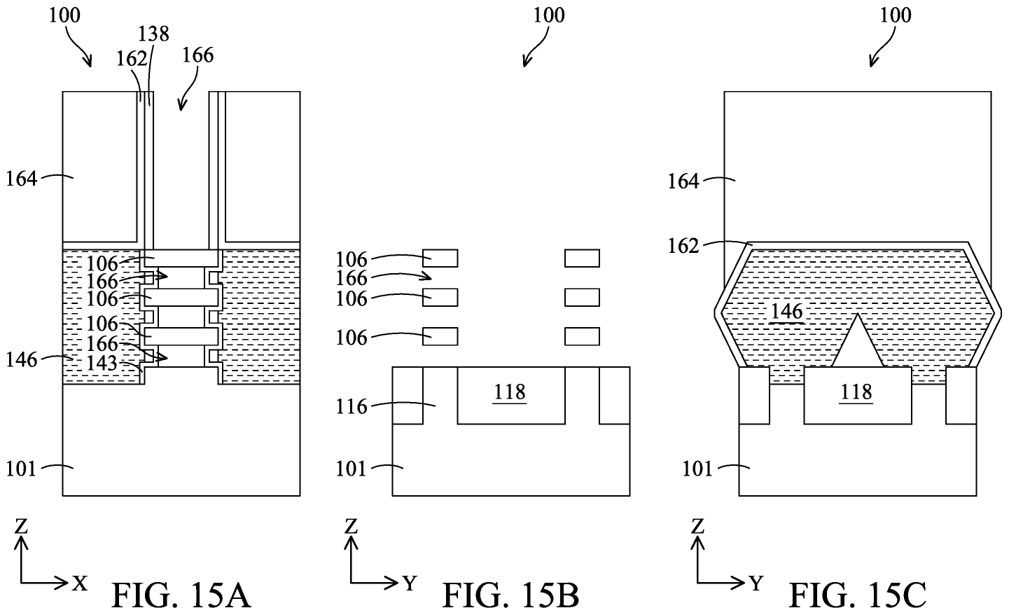

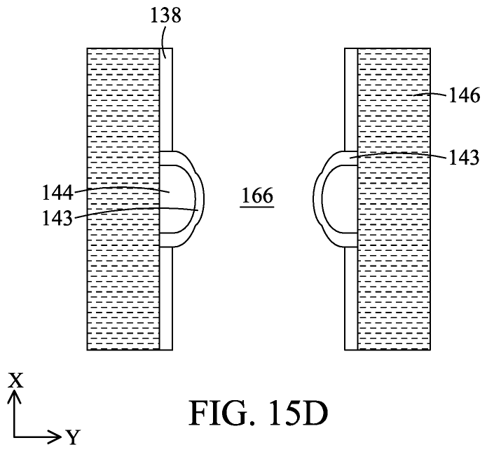

In FIGS. 15A-15D, the sacrificial gate structure 130 and the second semiconductor layers 108 are sequentially removed. The removal of the sacrificial gate structure 130 and the semiconductor layers 108 forms an opening 166 between gate spacers 138 and between adjacent first semiconductor layers 106. The first ILD layer 164 protects the epitaxial S/D features 146 during the removal processes. The sacrificial gate structure 130 can be removed using plasma dry etching and/or wet etching. The sacrificial gate electrode layer 134 may be first removed by any suitable process, such as dry etch, wet etch, or a combination thereof, followed by the removal of the sacrificial gate dielectric layer 132, which may also be performed by any suitable process, such as dry etch, wet etch, or a combination thereof. In some embodiments, a wet etchant such as a tetramethylammonium hydroxide (TMAH) solution can be used to selectively remove the sacrificial gate electrode layer 134 but not the gate spacers 138, the first ILD layer 164, the CESL 162, and the cap layer 143.

The removal of the sacrificial gate structure 130 exposes the first semiconductor layers 106 and the second semiconductor layers 108. An etch process, which may be any suitable etch processes, such as dry etch, wet etch, or a combination thereof, is then performed to remove the second semiconductor layers 108 and expose the cap layer 143 on the inner spacers 144. The etch process may be a selective etch process that removes the second semiconductor layers 108 but not the cap layer 143, the gate spacers 138, the first ILD layer 164, the CESL 162, and the first semiconductor layers 106. In cases where the second semiconductor layers 108 are made of SiGe or Ge and the first semiconductor layers 106 are made of Si, the chemistry used in the selective wet etching process removes the SiGe while not substantially affecting Si, the dielectric materials of the gate spacers 138, the cap layer 143, the inner spacers 144, the first ILD layer 164, and the CESL 162. In one embodiment, the second semiconductor layers 108 can be removed using a wet etchant such as, but not limited to, hydrofluoric (HF), nitric acid (HNO₃), hydrochloric acid (HCl), phosphoric acid (H₃PO₄), a dry etchant such as fluorine-based (e.g., F₂) or chlorine-based gas (e.g., Cl₂), or any suitable isotropic etchants. Upon completion of the etch process, a portion of the first semiconductor layers 106 not covered by the inner spacers 144 and the cap layer 143 is exposed in the opening 166. The cap layer 143 enhances the protection of the inner spacer 144 and prevents the etchants from breaking through the inner spacer 144 and damage the epitaxial S/D features 146.

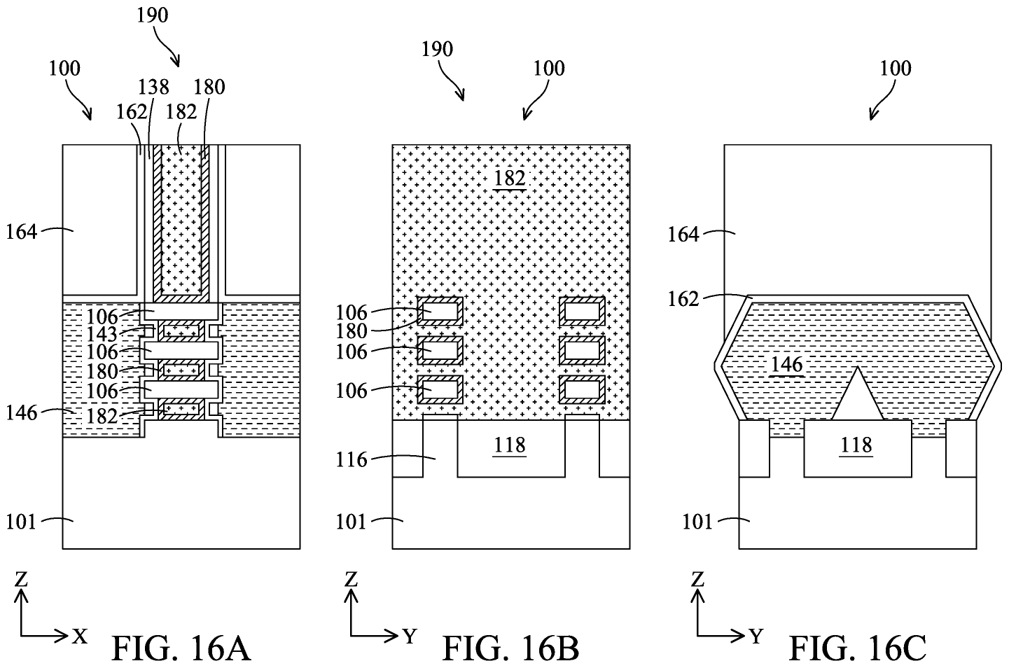

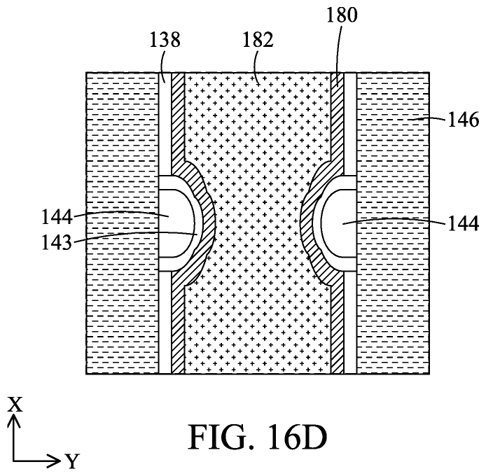

In FIGS. 16A-16D, replacement gate structures 190 are formed. The replacement gate structures 190 may each include a gate dielectric layer 180 and a gate electrode layer 182. In some embodiments, an interfacial layer (IL) (not shown) may be formed between the gate dielectric layer 180 and the first semiconductor layer 106. The IL may also form on the exposed surfaces of the substrate 101. The IL may include or be made of an oxide (e.g., silicon oxide) formed by thermal or chemical oxidation of the first semiconductor layers 106, a nitride (e.g., silicon nitride, silicon oxynitride, oxynitride, etc.), and/or a dielectric layer (e.g., hafnium silicate). Next, the gate dielectric layer 180 is formed on the exposed surfaces of the semiconductor device structure 100 (e.g., on the IL (if any), sidewalls of the gate spacers 138, the top surfaces of the first ILD layer 164, the CESL 162, and the cap layer 143). The gate dielectric layer 180 may be formed of a material chemically different than that of the sacrificial gate dielectric layer 132. The gate dielectric layer 180 may include or made of a high-k dielectric material, such as hafnium oxide (HfO₂), hafnium silicate (HfSiO), hafnium silicon oxynitride (HfSiON), hafnium aluminum oxide (HfAlO), hafnium lanthanum oxide (HfLaO), hafnium zirconium oxide (HfZrO), hafnium tantalum oxide (HfTaO), hafnium titanium oxide (HfTiO), lanthanum oxide (LaO), aluminum oxide (AlO), aluminum silicon oxide (AlSiO), zirconium oxide (ZrO), titanium oxide (TiO), tantalum oxide (Ta₂O₅), yttrium oxide (Y₂O₃), silicon oxynitride (SiON), or other suitable high-k materials. The gate dielectric layer 180 may be a conformal layer formed by a conformal process, such as an ALD process, a PECVD process, a molecular-beam deposition (MBD) process, or the like, or a combination thereof. The gate dielectric layer 180 may have a thickness in a range of about 0.3 nm to about 5 nm.

After formation of the IL (if any) and the gate dielectric layer 180, the gate electrode layer 182 is formed on the gate dielectric layer 180. The gate electrode layer 182 filles the openings 166 (FIG. 15A) and surrounds a portion of each of the first semiconductor layers 106. The gate electrode layer 182 includes one or more layers of conductive material, such as polysilicon, aluminum, copper, titanium, tantalum, tungsten, cobalt, molybdenum, tantalum nitride, nickel silicide, cobalt silicide, TIN, WN, WCN, TiAl, TiTaN, TiAlN, TaN, TaCN, TaC, TaSiN, metal alloys, other suitable materials, and/or combinations thereof. The gate electrode layers 182 may be formed by PVD, CVD, ALD, electro-plating, or other suitable method. In some embodiments, one or more optional conformal layers (not shown) can be conformally (and sequentially, if more than one) deposited between the gate dielectric layer 180 and the gate electrode layer 182. The one or more optional conformal layers can include one or more barrier and/or capping layers and one or more work-function tuning layers. The one or more barrier and/or capping layers may include or be a nitride, silicon nitride, carbon nitride, and/or aluminum nitride of tantalum and/or titanium; a nitride, carbon nitride, and/or carbide of tungsten; the like; or a combination thereof. The one or more work-function tuning layers may include or be a nitride, silicon nitride, carbon nitride, aluminum nitride, aluminum oxide, and/or aluminum carbide of titanium and/or tantalum; a nitride, carbon nitride, and/or carbide of tungsten; cobalt; platinum; the like; or a combination thereof.

Portions of the gate electrode layer 182, the one or more optional conformal layers (if any), and the gate dielectric layer 180 above the top surfaces of the first ILD layer 164, the CESL 162, and the gate spacers 138 may be removed by a planarization process, such as by a CMP process. After the CMP process, the top surfaces of the first ILD layer 164, the CESL 162, the gate spacers 138, and the gate electrode layer 182 are substantially co-planar.

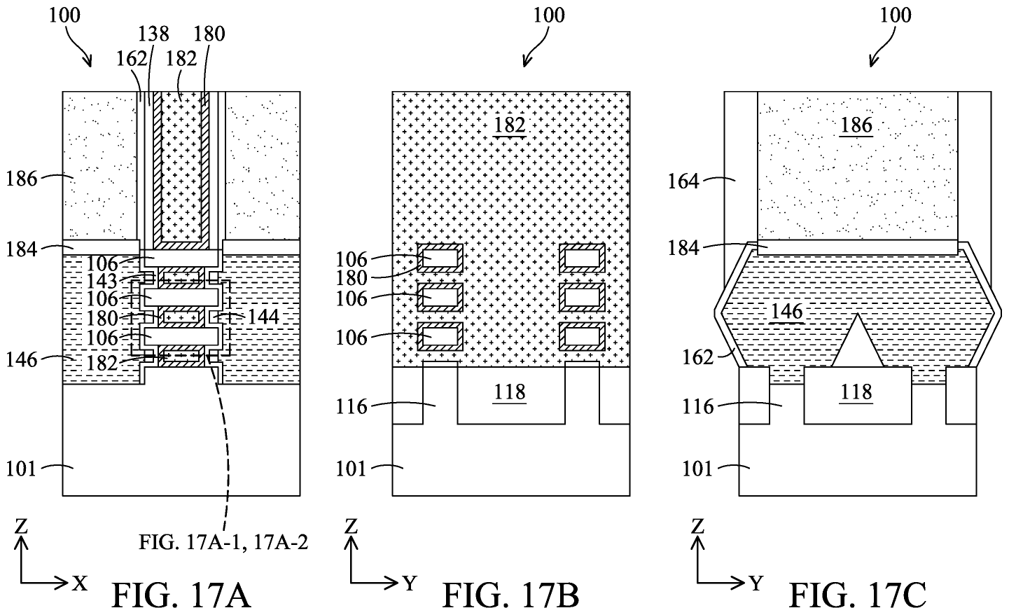

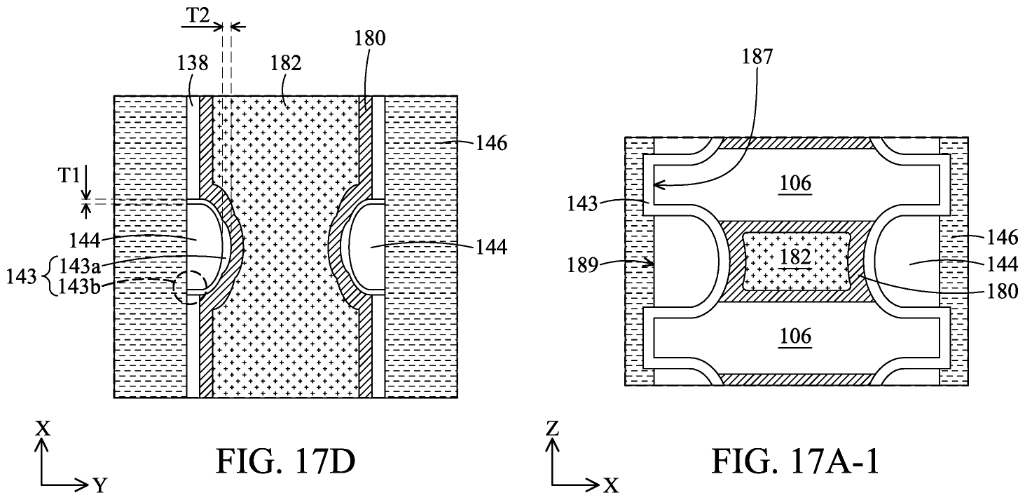

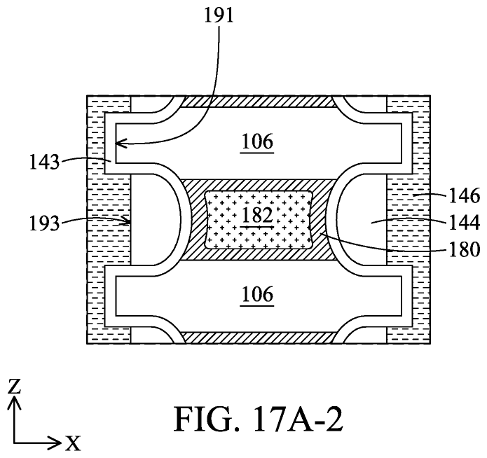

In FIGS. 17A-17D, contact openings are formed through the first ILD layer 164, and the CESL 162 to expose the epitaxial S/D feature 146. A silicide layer 184 is then formed on the S/D epitaxial features 146, and a source/drain (S/D) contact 186 is formed in the contact opening on the silicide layer 184. The S/D contact 186 may include an electrically conductive material, such as Ru, Mo, Co, Ni, W, Ti, Ta, Cu, Al, TiN, or TaN. While not shown, a barrier layer (e.g., TiN, TaN, or the like) may be formed on sidewalls of the contact openings prior to forming the S/D contacts 186.

After the formation of the contact openings, a silicide layer 184 is formed on the epitaxial S/D features 146. The silicide layer 184 conductively couples the epitaxial S/D features 146 to subsequent S/D contacts 186 formed in the contact openings. The silicide layer 184 may be formed by depositing a metal source layer over the epitaxial S/D features 146 and performing a rapid thermal annealing process. During the rapid anneal process, the portion of the metal source layer over the epitaxial S/D features 146 reacts with silicon in the epitaxial S/D features 146 to form the silicide layer 184. Unreacted portion of the metal source layer is then removed. The silicide layer 184 may include a metal or metal alloy silicide, and the metal includes a noble metal, a refractory metal, a rare earth metal, alloys thereof, or combinations thereof. Next, a conductive material is formed in the contact openings and form the S/D contacts 186. The conductive material may be made of a material including one or more of Ru, Mo, Co, Ni, W, Ti, Ta, Cu, Al, TiN and TaN. While not shown, a barrier layer (e.g., TiN, TaN, or the like) may be formed on sidewalls of the contact openings prior to forming the S/D contacts 186. Then, a planarization process, such as CMP, is performed to remove excess deposition of the contact material and expose the top surface of the gate electrode layer 182.

As shown in FIG. 17D, the cap layer 143 between two adjacent semiconductor layers 106 may include a first portion 143a and a second portion 143b. The first portion 143a is extended between and in contact with the inner spacer 144 and the gate dielectric layer 180. The second portion 143b is disposed between and in contact with the inner spacer 144 and the gate spacer 138. The second portion 143b is also in contact with the epitaxial S/D feature 146. The second portion 143b of the cap layer 143 may have the thickness T1 and the first portion 143a of the cap layer 143 may have a thickness T2 greater than the thickness T1.

FIG. 17A-1 illustrates an enlarged view of a portion of the semiconductor device structure 100 shown in FIG. 17A, in accordance with some embodiments. In this embodiment, the cap layer 143 is a continuous layer disposed between and in contact with the inner spacer 144, the first semiconductor layer 106, the second semiconductor layer 108, and the epitaxial S/D features 146. The cap layer 143 is extended to separate the first semiconductor layers 106 from the inner spacers 144 entirely. Each of the inner spacers 144 are separated from the first semiconductor layers 106 and the gate dielectric layer 180 by the cap layer 143. A portion of at least one of the first semiconductor layers 106 and a portion of the cap layer 143 define a first interface 187, and a portion of the inner spacer 144 and a portion of the epitaxial S/D feature 146 define a second interface 189. In some embodiments, the first interface 187 and the second interface 189 are substantially aligned or co-planar. Portions of the cap layer 143 are extended into the epitaxial S/D feature 146.

FIG. 17A-2 illustrates an enlarged view of a portion of the semiconductor device structure 100 shown in FIG. 17A, in accordance with some embodiments. The embodiment shown in FIG. 17A-2 is similar to the embodiment of FIG. 17A-1 except that the inner spacers 144 are further recessed to allow a greater amount of the epitaxial S/D feature 146 to extend into the region between adjacent first semiconductor layers 106. Likewise, a portion of at least one of the first semiconductor layers 106 and a portion of the cap layer 143 define a first interface 191, and a portion of the inner spacer 144 and a portion of the epitaxial S/D feature 146 define a second interface 193. In some embodiments, the first interface 191 and the second interface 193 are off set from each other (i.e., not aligned). Portions of the cap layer 143 are extended into the epitaxial S/D feature 146.

It is understood that the semiconductor device structure 100 may undergo further complementary metal oxide semiconductor (CMOS) and/or back-end-of-line (BEOL) processes to form various features such as transistors, contacts/vias, interconnect metal layers, dielectric layers, passivation layers, etc. The semiconductor device structure 100 may also include backside contacts (not shown) on the backside of the substrate 101 so that either source or drain of the epitaxial S/D features 146 is connected to a backside power rail (e.g., positive voltage VDD or negative voltage VSS) through the backside contacts.

Various embodiments or examples described herein offer multiple advantages over the state-of-art technology. According to embodiments of the present disclosure, wire release induced damages to S/D features of nanostructure channel FETs can be prevented by covering exposed surfaces of first semiconductor layers 106 (nanostructure channel layers) and second semiconductor layers 108 with a silicon-based cap layer 143 prior to formation of inner spacer 144. The cap layer can reduce or eliminate germanium diffusion through the inner spacer at and/or near the end of nanostructure channels during high temperature processes. The cap layer can also effectively retard etchant chemicals used during the replacement gate process, thereby protecting the integrality of the epitaxial S/D features.

An embodiment is a semiconductor device structure. The structure includes a plurality of semiconductor layers vertically stacked, a plurality of inner spacers, each being disposed between two adjacent semiconductor layers. The structure also includes a source/drain feature in contact with each of the inner spacers, a gate electrode layer surrounding a portion of each of the plurality of the semiconductor layers, and a cap layer disposed between the source/drain feature and each of the plurality of the semiconductor layers.

Another embodiment is a semiconductor device structure. The structure includes a plurality of semiconductor layers vertically stacked, a plurality of inner spacers, each being disposed between two adjacent semiconductor layers. The structure also includes a source/drain feature in contact with each of the inner spacers, a gate electrode layer surrounding a portion of each of the plurality of the semiconductor layers, and a cap layer separating each of the plurality of the semiconductor layers from the source/drain feature wherein a portion of at least one of the plurality of the semiconductor layers and a portion of the cap layer define a first interface, and wherein a portion of the inner spacer and the source/drain feature define a second interface that is offset from the first interface.

A further embodiment is a method for forming a semiconductor device structure. The method includes forming a stack of semiconductor layers over a substrate, the stack of the semiconductor layers comprising a plurality of first semiconductor layers and a plurality of second semiconductor layers alternatingly stacked, forming a fin structure from the stack of the semiconductor layers and the substrate, forming a sacrificial gate structure and a gate spacer over a portion of the fin structure, removing portions of the fin structure not covered by the sacrificial gate structure and the gate spacer to expose a portion of the substrate, removing edge portions of the second semiconductor layers to form cavities between adjacent first semiconductor layers, selectively forming a cap layer on exposed surfaces of each of the first and second semiconductor layers, forming an inner spacer on the cap layer within the cavities, forming a source/drain feature on opposite sides of the sacrificial gate structure and the gate spacer, wherein the source/drain feature is in contact with the cap layer and the inner spacer. The method also includes removing the sacrificial gate structure and the plurality of second semiconductor layers to expose portions of the plurality of first semiconductor layers and the cap layer, and forming a gate electrode layer to surround the exposed portion of at least one of the plurality of first semiconductor layers, wherein the gate electrode layer is separated from the inner spacer by the cap layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device structure, comprising:
a plurality of semiconductor layers vertically stacked;
a plurality of inner spacers, each being disposed between two adjacent semiconductor layers among the plurality of semiconductor layers;
a source/drain feature in contact with each of the inner spacers;
a gate electrode layer surrounding a portion of each of the plurality of the semiconductor layers; and
a cap layer disposed between the source/drain feature and each of the plurality of the semiconductor layers.

2. The semiconductor device structure of claim 1, wherein each of the inner spacers has at least three surfaces in contact with the cap layer and one surface in contact with the source/drain feature.

3. The semiconductor device structure of claim 1, further comprising:
a gate dielectric layer disposed between the gate electrode layer and each of the plurality of the semiconductor layers.

4. The semiconductor device structure of claim 3, wherein a portion of the cap layer is disposed between and in contact with the gate dielectric layer and each of the inner spacers.

5. The semiconductor device structure of claim 3, further comprising:
a gate spacer in contact with the cap layer and portions of the gate dielectric layer.

6. The semiconductor device structure of claim 5, wherein a portion of the cap layer is disposed between and in contact with the gate spacer and each of the inner spacers.

7. The semiconductor device structure of claim 6, wherein a portion of the cap layer is further in contact with the source/drain feature.

8. The semiconductor device structure of claim 1, wherein a portion of at least one of the semiconductor layers and a portion of the cap layer define a first interface, a portion of the inner spacer and a portion of the source/drain feature define a second interface, and the first interface and the second interface are substantially aligned.

9. The semiconductor device structure of claim 1, wherein a portion of at least one of the semiconductor layers and a portion of the cap layer define a first interface, a portion of the inner spacer and a portion of the source/drain feature define a second interface, and the first interface and the second interface are off set from each other.

10. A semiconductor device structure, comprising:
a plurality of semiconductor layers vertically stacked;
a plurality of inner spacers, each being disposed between two adjacent semiconductor layers;
a source/drain feature in contact with each of the inner spacers;
a gate electrode layer surrounding a portion of each of the plurality of the semiconductor layers; and
a cap layer separating each of the plurality of the semiconductor layers from the source/drain feature,
wherein a portion of at least one of the plurality of the semiconductor layers and a portion of the cap layer define a first interface, and
wherein a portion of the inner spacer and the source/drain feature define a second interface that is offset from the first interface.

11. The semiconductor device structure of claim 10, further comprising:
a gate dielectric layer disposed between the semiconductor layer and the gate electrode layer.

12. The semiconductor device structure of claim 11, wherein the first portion is disposed between and in contact with the gate dielectric layer and each of the inner spacers.

13. The semiconductor device structure of claim 11, wherein each of the inner spacers has a first side in contact with the cap layer and a second side in contact with the source/drain feature.

14. The semiconductor device structure of claim 11, further comprising:
a gate spacer in contact with portions of the gate dielectric layer, wherein the second portion of the cap layer is further in contact with the gate spacer.

15. The semiconductor device structure of claim 14, wherein a portion of the gate dielectric layer is disposed between and in contact with the gate spacer and the gate electrode layer.

16. The semiconductor device structure of claim 10, wherein a portion of the cap layer is extended into the source/drain feature.

17. The semiconductor device structure of claim 10, wherein the cap layer is a pure silicon or doped silicon.

18. A method for forming a semiconductor device structure, comprising:
forming a stack of semiconductor layers over a substrate, the stack of the semiconductor layers comprising a plurality of first semiconductor layers and a plurality of second semiconductor layers alternatingly stacked;
forming a fin structure from the stack of the semiconductor layers and the substrate;
forming a sacrificial gate structure and a gate spacer over a portion of the fin structure;
removing portions of the fin structure not covered by the sacrificial gate structure and the gate spacer to expose a portion of the substrate;
removing edge portions of the second semiconductor layers to form cavities between adjacent first semiconductor layers;
selectively forming a cap layer on exposed surfaces of each of the first and second semiconductor layers;
forming an inner spacer on the cap layer within the cavities;
forming a source/drain feature on opposite sides of the sacrificial gate structure and the gate spacer, wherein the source/drain feature is in contact with the cap layer and the inner spacer;
removing the sacrificial gate structure and the plurality of second semiconductor layers to expose portions of the plurality of first semiconductor layers and the cap layer; and
forming a gate electrode layer to surround the exposed portion of at least one of the plurality of first semiconductor layers, wherein the gate electrode layer is separated from the inner spacer by the cap layer.

19. The method of claim 18, further comprising:
prior to forming a gate electrode layer, forming a gate dielectric layer to surround a portion of each of the plurality of the first semiconductor layers, wherein a portion of the cap layer is disposed between and in contact with the gate dielectric layer and the inner spacer.

20. The method of claim 19, wherein the cap layer is a pure silicon or doped silicon.
